(19) United States
(12) Patent Application Publication
(10) Pub. No.: US 2006/0273316 A1
(43) Pub. Date: Dec. 7, 2006

(54) Array substrate having enhanced aperture ratio, method of manufacturing the same and display apparatus having the same

(75) Inventors: Yong-Ho Yang, Suwon-si (KR); Joo-Sun Yoon, Seoul (KR); Seung-Gyu Tae, Suwon-si (KR); Hyung-Don Na, Seoul (KR); Jin-Suk Park, Seoul (KR); Ki-Hun Jeong, Seoul (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/437,505

(22) Filed: May 18, 2006

(30) Foreign Application Priority Data
Jun. 1, 2005 (KR) 2005-46863

(51) Int. Cl. H01L 29/04

(52) U.S. Cl. 257/59; 257/72; 438/149

(57) ABSTRACT

An array substrate includes a transparent substrate, a thin film transistor (TFT), a pixel electrode and a storage capacitor. The TFT includes a gate electrode formed on the transparent substrate, a first gate insulation layer formed on the gate electrode, a second gate insulation layer formed on the first gate insulation layer, a semiconductor layer formed on the second gate insulation layer, and a data electrode formed on the semiconductor layer. The pixel electrode is electrically connected to the data electrode. The storage capacitor includes a first storage capacitor electrode that is spaced apart from the gate electrode, and a second storage capacitor electrode formed on the first gate insulation layer such that the second storage capacitor electrode is disposed over the first storage capacitor electrode. The second storage capacitor electrode is constructed from the material which is also used to form the data electrode.

### CROSS REFERENCE TO RELATED APPLICATIONS

This application relies for priority upon Korean Patent Application No. 2005-46863 filed on Jun. 1, 2005, the contents of which are herein incorporated by reference in its entirety.

### BACKGROUND OF THE INVENTION

1. Field of the Invention

The present invention relates to an array substrate having enhanced aperture ratio, a method of manufacturing the array substrate, and a display apparatus having the array substrate. More particularly, the present invention relates to an array substrate having enhanced aperture ratio without reducing storage capacitance, a method of manufacturing the array substrate, and a display apparatus having the array substrate.

2. Description of the Related Art

A liquid crystal display (LCD) apparatus displays an image by using liquid crystal having optical anisotropy. The LCD apparatus includes an upper substrate, a lower substrate and a liquid crystal layer disposed between the upper substrate and the lower substrate.

A conventional LCD apparatus is described below with reference to FIG. 1. FIG. 1 is a cross-sectional view illustrating a portion of a conventional LCD panel. Referring to FIG. 1, a conventional LCD panel 100 includes an array substrate 110, a color filter substrate 120 facing the array substrate 110, and a liquid crystal layer 130 disposed between the array substrate 110 and the color filter substrate 120. The color filter substrate 120 includes a light-blocking layer 121, a color filter layer 122 and a common electrode 123.

The array substrate 110 includes a thin film transistor (TFT) 101, a storage capacitor 102 and a pixel electrode 103.

The TFT 101 includes a gate electrode 104, a gate insulation layer 105, a semiconductor layer 106 and a data electrode 107. When a gate voltage is applied to the gate electrode 104, the TFT 101 is turned on, and a data voltage of the data electrode 107 is applied to the pixel electrode 103. When the data voltage is applied to the pixel electrode 103, an electric field is generated between the pixel electrode 103 of the array substrate 110 and the common electrode 123 of the color filter substrate 120 to alter an arrangement of liquid crystal molecules of the liquid crystal layer 130 disposed between the array substrate 110 and the color filter substrate 120. When the arrangement of the liquid crystal molecules is altered, an optical transmittance is changed to display an image.

The storage capacitor 102 supplements a liquid crystal capacitor defined by the pixel electrode 103 of the array substrate 110 and the common electrode 123 of the color filter substrate 120. In detail, the storage capacitor 102 prevents electric coupling of the pixel electrode 103, when the data voltage is applied to the pixel electrode 103. The storage capacitor 102 also supplements the liquid crystal capacitor for maintaining the data voltage for one frame. Therefore, when a capacitance of the storage capacitor 102 increases, a display quality of the LCD panel 100 is enhanced.

The magnitude of the capacitance of the storage capacitor 102 is inversely proportional to a distance between two electrodes defining the storage capacitor 102 and linearly proportional to an area of the two electrodes. In other words, when a thickness of the gate insulation layer 105 decreases, and an overlapping area between the two electrodes defining the storage capacitor 102 increases, the magnitude of the capacitance of the storage capacitor 102 increases.

However, when the overlapping area between the two electrodes defining the storage capacitor 102 is increased to increase the magnitude of the capacitance of the storage capacitor 102, an aperture ratio is decreased. When the thickness of the gate insulation layer 105 is decreased in order to increase the magnitude of the capacitance of the storage capacitor 102, a parasitic capacitance between the gate electrode 104 and the data electrode 107 is increased.

The TFT 101 includes gate electrode 104 and data electrode 107 which are spaced apart from each other by the gate insulation layer 105. When the gate insulation layer 105 becomes thinner, the parasitic capacitance between the gate electrode 104 and the data electrode 107 increases and this adversely affects the performance of the liquid crystal layer 130. Since the parasitic capacitance is a source of direct current (DC), when the direct current is applied to the parasitic capacitance, liquid crystal of the liquid crystal layer 130 is damaged.

Furthermore, when a thickness of the gate insulation layer 105 is reduced, a possibility of electric short between the gate electrode 104 and the data electrode 107 increases. Thus there is a possibility of failure of the conventional LCD panel 100.

In the prior art the above problems are addressed by increasing the thickness of the gate insulation layer 105 which is also used as an organic layer for the storage capacitor 102 by simultaneously forming the gate insulation layer 105 on the gate electrode 104. That is, in order to increase the capacitance of the storage capacitor 102, an overlapping area of the two electrodes defining the storage capacitor 102 is increased, which in turn reduces the aperture ratio. Therefore, there still exists a problem of the reduced aperture ratio.

### SUMMARY OF THE INVENTION

The present invention provides an array substrate having enhanced aperture ratio.

The present invention also provides a method of manufacturing the above array substrate.

The present invention also provides a display apparatus having the above array substrate.

In an example of the array substrate according to the present invention, the array substrate includes a transparent substrate, a thin film transistor, a pixel electrode and a storage capacitor. The thin film transistor includes a gate electrode formed on the transparent substrate, a first gate insulation layer formed on the gate electrode, a second gate insulation layer formed on the first gate insulation layer, a semiconductor layer formed on the second gate insulation layer, and a data electrode formed on the semiconductor layer. The pixel electrode includes a transparent conductive metal to electrically connect to the data electrode. The storage capacitor includes a first storage capacitor electrode that is spaced apart from the gate electrode of the thin film transistor, and a second storage capacitor electrode formed on the first gate insulation layer such that the second storage capacitor electrode is disposed over the first storage capacitor electrode. The second storage capacitor electrode includes same material as that of the data electrode of the thin film transistor.

In an example of a method of manufacturing an array substrate according to the present invention, a gate electrode, a first capacitor electrode and a gate line that is electrically connected to the gate electrode are formed by patterning a metal layer formed on a transparent substrate. A first gate insulation layer is formed on the transparent substrate having the gate electrode, the first capacitor electrode and the gate line formed thereon. A second gate insulation layer and a semiconductor layer are formed in a thin film transistor region corresponding to the gate electrode by removing a portion of a preliminary second insulation layer and a preliminary semiconductor layer formed on the preliminary second insulation layer. A data electrode, a second storage capacitor electrode corresponding to the first storage capacitor electrode, and a data line that is electrically connected to the data electrode are formed by patterning a metal layer formed on the transparent substrate having the semiconductor layer formed thereon. A second contact hole is formed by removing a portion of an insulation layer formed on the transparent substrate having the data electrode, the second storage capacitor electrode and the data line formed thereon. Then, a pixel electrode that is electrically connected to the data electrode through the second contact hole is formed by patterning an optically transparent and electrically conductive layer formed on the insulation layer having the second contact hole.

In another example of a method of manufacturing an array substrate according to the present invention, a gate electrode, a first capacitor electrode, a gate line that is electrically connected to the gate electrode, and a gate pad is formed by patterning a metal layer formed on a transparent substrate. A first gate insulation layer is formed on the transparent substrate having the gate electrode, the first capacitor electrode and the gate line formed thereon. A second gate insulation layer and a semiconductor layer are formed in a thin film transistor region corresponding to the gate electrode by removing a portion of a preliminary second insulation layer and a preliminary semiconductor layer formed on the preliminary second insulation layer. A portion of the first insulation layer is removed to form a first contact hole that exposes the gate pad. A data electrode, a second storage capacitor electrode corresponding to the first storage capacitor electrode, a gate pad buffer layer that is electrically connected to the gate pad through the first contact hole, and a data line that is electrically connected to the data electrode are formed by patterning a metal layer formed on the transparent substrate having the semiconductor layer formed thereon. A second contact hole is formed by removing a portion of an insulation layer formed on the transparent substrate having the data electrode, the second storage capacitor electrode and the data line formed thereon. A pixel electrode that is electrically connected to the data electrode through the second contact hole is formed by patterning an optically transparent and electrically conductive layer formed on the insulation layer having the second contact hole.

In an example of the display apparatus according to the present invention, the display apparatus includes a liquid crystal capacitor and a storage capacitor. The liquid crystal capacitor is electrically connected to a thin film transistor having a gate electrode, a data electrode including source electrode and a drain electrode that is spaced apart from the drain electrode, and a gate insulation layer that is disposed between the gate electrode and the data electrode to electrically insulate the gate electrode from the data electrode. The storage capacitor is electrically connected to the liquid crystal capacitor in parallel to maintain a pixel voltage applied to the liquid crystal capacitor for one frame. The storage capacitor includes a first storage capacitor electrode, a second storage capacitor and the gate insulation layer disposed between the first and second storage capacitor electrodes. The gate insulation layer corresponding to the thin film transistor is thicker than the gate insulation layer corresponding to the storage capacitor.

According to the present invention, the gate insulation layer has a double layered structure having the first insulation layer and the second insulation layer at a region wherein the thin film transistor is formed to prevent deterioration of liquid crystal caused by the direct current (DC) and electrical short, and the gate insulation layer has only the first insulation layer at the storage capacitor to enhance capacitance of the storage capacitor.

Additionally, the first insulation layer has a lower dielectric constant than that of the second insulation layer to enhance capacitance of the storage capacitor without increasing the size of the storage capacitor.

### BRIEF DESCRIPTION OF THE DRAWINGS

The above and other features and advantages of the present invention will become more apparent in light of the description below of several exemplary embodiments with reference to the accompanying drawings, in which:

FIG. 1 is a cross-sectional view illustrating a conventional LCD panel;

FIG. 2 is an equivalent circuit diagram of pixels in an LCD apparatus;

FIG. 3 is a layout illustrating an array substrate according to one embodiment of the present invention; and

FIGS. 4A to 4F are cross-sectional views illustrating a method of manufacturing an array substrate according to an embodiment of the present invention.

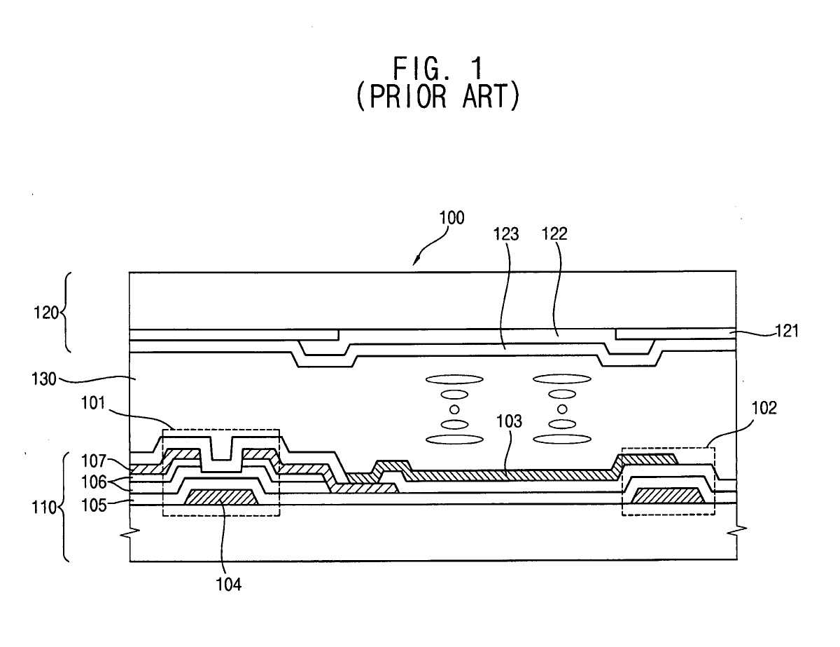

### DESCRIPTION OF THE EMBODIMENTS

It should be understood that the exemplary embodiments of the present invention described below may be modified in many different ways without departing from the inventive principles disclosed herein, and the scope of the present invention is therefore not limited to these particular embodiments. Rather, these embodiments are provided so that this disclosure will be thorough and complete, and will fully convey the concept of the invention to those skilled in the art by way of example and not of limitation.

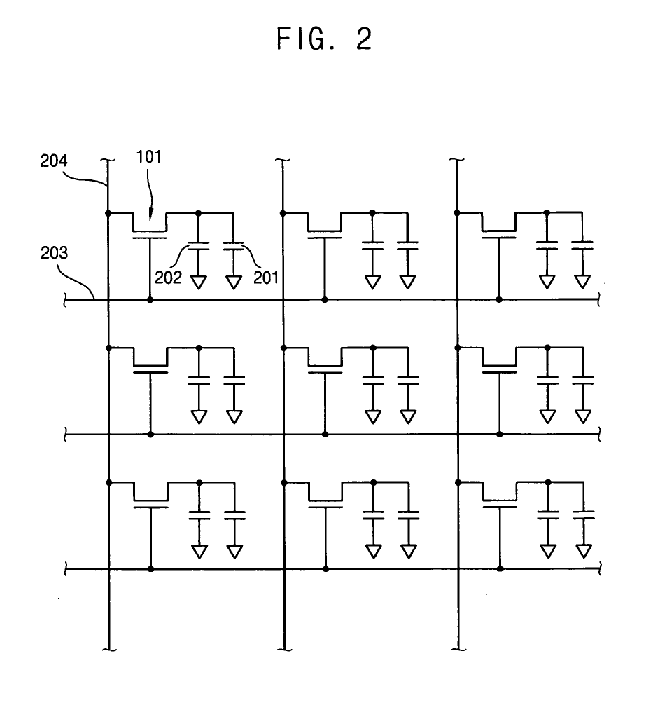

FIG. 2 is an equivalent circuit diagram of pixels in an LCD apparatus.

Referring to FIG. 2, an LCD apparatus includes a plurality of data lines 204 and a plurality of gate lines 203. Each of the data lines 204 extend along a first direction and are spaced apart from one another. Each of the gate lines 203 extend along a second direction that is substantially perpendicular to the first direction and are spaced apart from one another. The gate lines 203 are formed under a gate insulation layer (not shown) and the data lines 204 are formed over the gate insulation layer. In other words, the gate insulation layers are disposed between the gate lines 203 and the data lines 204.

Two adjacent data lines 204 and the two adjacent to gate lines 203 define a pixel. The pixel includes a thin film transistor (TFT) 101, a storage capacitor 202 and a liquid crystal capacitor 201. The TFT 101 includes a gate electrode, a drain electrode, a source electrode and a semiconductor layer.

The gate electrode of the TFT 101 is electrically connected to one of the gate lines 203. The source electrode of the TFT 101 is electrically connected to one of the data lines 204. The drain electrode of the TFT 101 is electrically connected to the storage capacitor 202 and the liquid crystal capacitor 201.

When gate voltage is applied to the gate electrode of the TFT 101, the TFT 101 is turned on. When the TFT 101 is turned on, a pixel voltage of the data line 204 is applied to the liquid crystal capacitor 201 and the storage capacitor 202 through the TFT 101. When the pixel voltage is applied to the liquid crystal capacitor 201, the arrangement of liquid crystal molecules between the pixel electrode and the common electrode defining the liquid crystal capacitor 201 is altered to change optical transmittance. Therefore, an image is displayed.

The storage capacitor 202 maintains the pixel voltage of the liquid crystal capacitor 201 during one frame.

The pixel electrode of the liquid crystal capacitor 201 includes an electrically conductive and optically transparent material such as indium tin oxide (ITO), or indium zinc oxide (IZO).

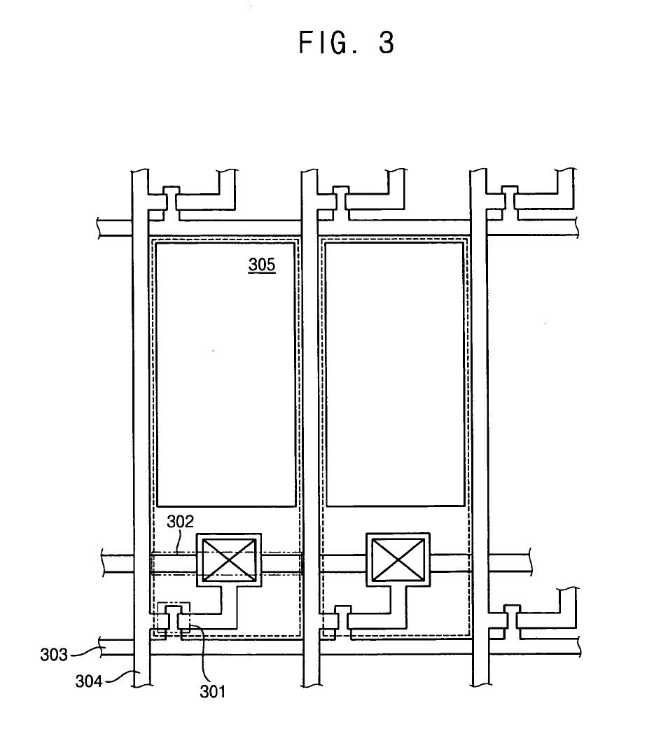

FIG. 3 is a layout illustrating an array substrate according to an example embodiment of the present invention.

FIG. 3 discloses an array substrate according to an embodiment of the present invention which includes a thin film transistor (TFT) 301, a storage capacitor 302, a pixel electrode 305, a gate line 303 and a data line 304.

According to the present invention, a dielectric layer is formed for the capacitor storage capacitor 302 such that the dielectric layer is thinner than the gate insulation layer. Therefore, an aperture ratio is enhanced without reducing capacitance of the storage capacitor 302.

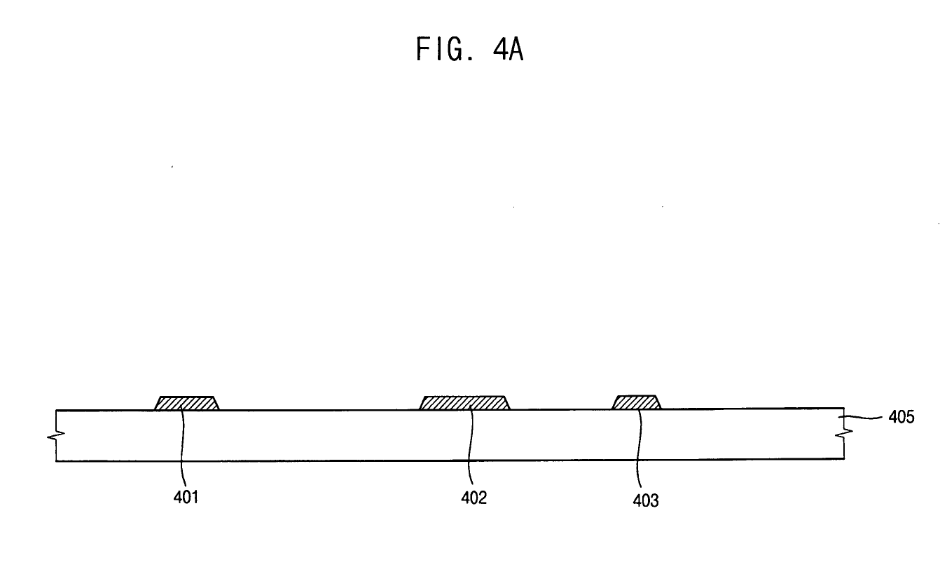

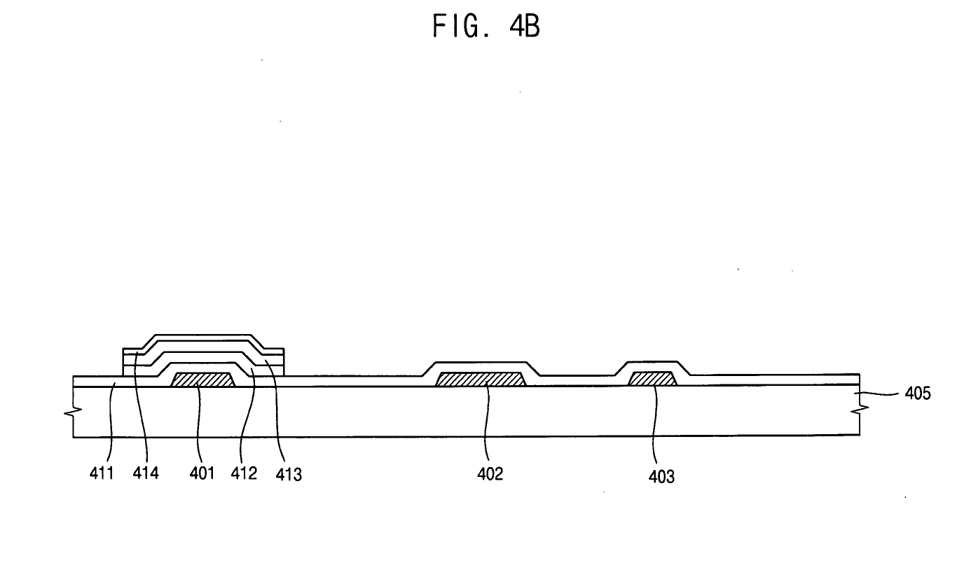

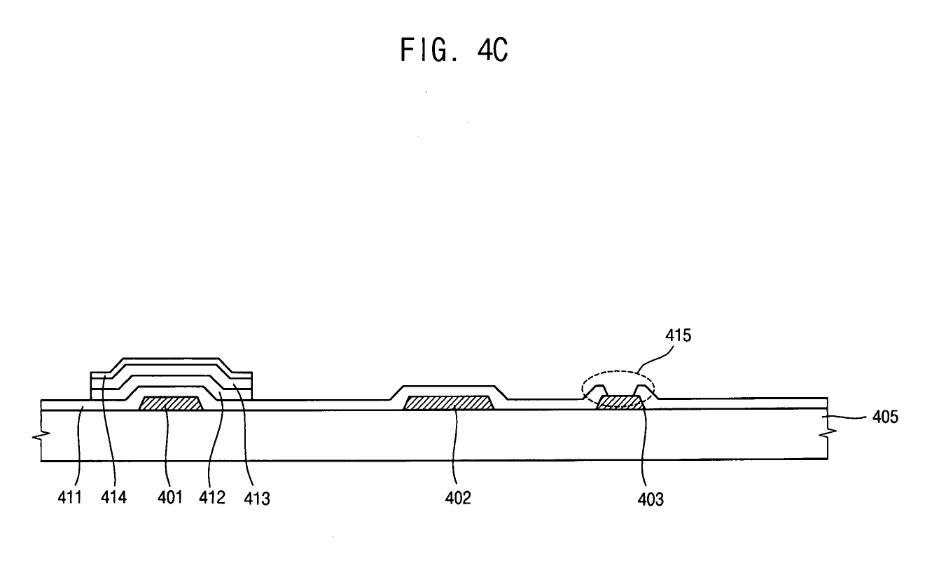

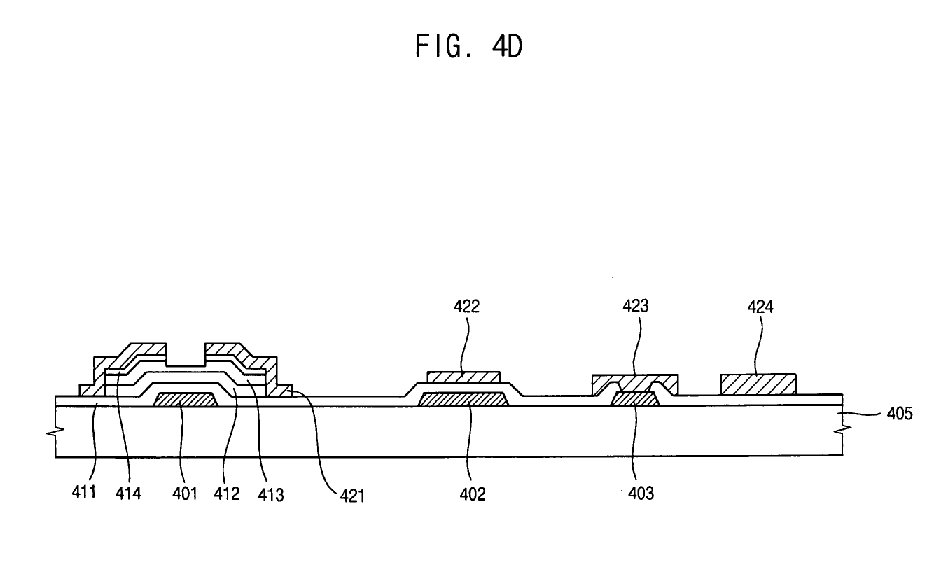

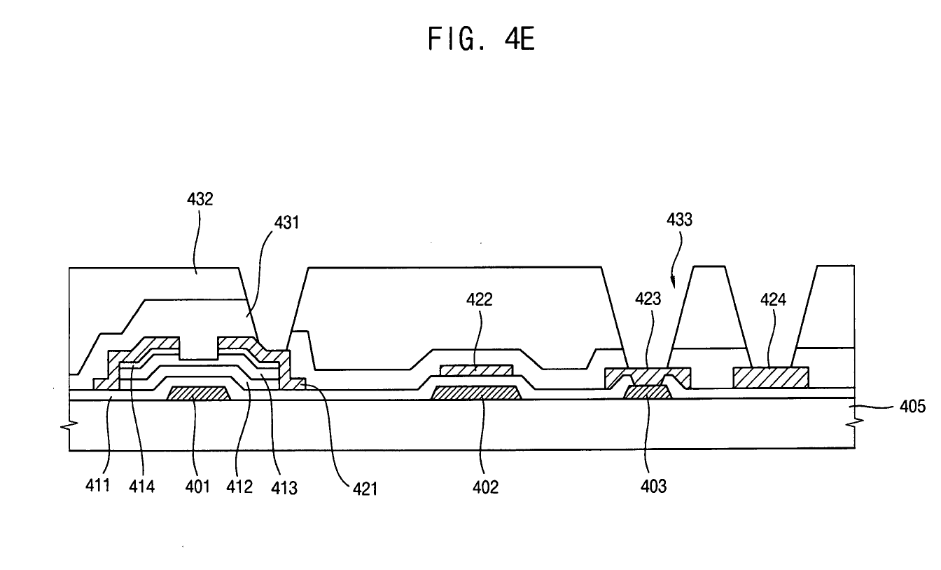

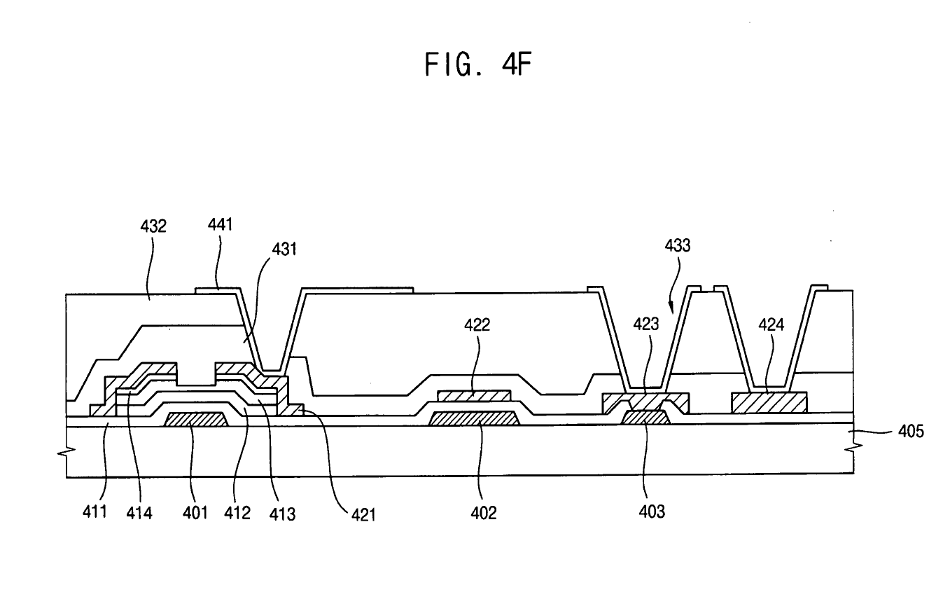

Hereinafter, a method of manufacturing the array substrate is explained referring to FIGS. 4A to 4F. FIG. 4F shows a structure of the array substrate in more detail.

FIGS. 4A to 4F are cross-sectional views illustrating a method of manufacturing an array substrate according to an embodiment of the present invention.

Referring to FIG. 4A, after a conducting layer (not shown) is formed on a transparent substrate 405, a photosensitive layer (not shown) is formed on the conducting layer. The photosensitive layer is patterned to form a photolithographic mask (not shown). Thereafter, the conducting layer is patterned through the photolithographic mask to form a gate electrode 401, a first storage capacitor electrode 402 and a gate pad 403. In this example, the conducting layer is a single layer structure. Alternatively, the conducting layer may be formed from a multi-layer structure. The conducting layer may be formed from aluminum (Al), molybdenum (Mo), tungsten (W), neodymium (Nd), copper (Cu), or an alloy.

Referring to FIG. 4B, a layer of insulating material is formed on the transparent substrate 405 over gate electrode 401, the first storage capacitor electrode 402 and the gate pad 403 formed thereon to form a first gate insulation layer 411, and a preliminary second gate insulating layer (not shown). For example, silicon oxide (SiOx) and silicon nitride (SiNx) are coated in sequence to form the first gate insulation layer 411 and the preliminary second gate insulation layer, respectively. Alternatively, one of silicon oxide (SiOx) and silicon nitride (SiNx) may be coated only, so that the first gate insulation layer 411 and the preliminary second gate insulation layer have same material.

A preliminary semiconductor layer (not shown) including poly-silicon or amorphous silicon is formed on the preliminary second gate insulation layer, and a preliminary ohmic contact layer (not shown) is formed on the preliminary semiconductor layer. Then, a photolithographic mask is formed on the preliminary ohmic contact layer, and the preliminary ohmic contact layer, the preliminary semiconductor layer and the preliminary second gate insulation layer are patterned to form the ohmic contact layer 414, the semiconductor layer 413 and the second gate insulation layer 412, respectively.

The first gate insulation layer 411, or the first and second gate insulation layers 411 and 412 respectively, define a gate insulation layer assembly. The thickness of gate insulation assembly associated with the gate electrode 401 is different than the thickness of the gate insulation layer assembly associated with the first storage capacitor electrode 402. More particularly, the gate insulation assembly associated with the gate electrode 401 is thicker than the gate insulation assembly associated with the first storage capacitor electrode 402. The first gate insulation layer 411 may be constructed using an oxide of silicon (SiOx) with a thickness ranging from about 1000 angstroms to about 2000 angstroms. The second gate insulation layer 412 may be constructed using silicon nitride (SiNx) with a thickness ranging from about 2000 angstroms to about 3000 angstroms. The semiconductor layer 413 may be constructed from poly-silicon or amorphous silicon, with a thickness ranging from about 1000 angstroms to about 3000 angstroms. Silicon oxide (SiOx) etches more slowly than silicon nitride (SiNx). More particularly, the etching selection ratio of the first gate insulation layer 411 to the second gate insulation layer is, for example, higher than 10:1. Therefore, when the preliminary second gate insulation layer is etched to form the second gate insulation layer 412, the first gate insulation layer 411 is etched only very slightly.

The second gate insulation layer 412 has a uniform thickness, and the first and second gate insulation layers 411 and 412 possess uniform characteristics.

Referring to FIG. 4C, a photolithographic mask (not shown) is disposed on the gate pad 403, and a portion of the first gate insulation layer 411, which is disposed over the gate pad 403, is removed to form a first contact hole 415.

Referring to FIG. 4D, a conducting layer is formed on the transparent substrate 405 including the semiconductor layer 413 and the ohmic contact layer 414 formed thereon, and the conducting layer is patterned to form a data electrode 421, a second storage capacitor electrode 422, a gate pad buffer layer 423 and a data pad 424.

Referring to FIGS. 4E and 4F, a first insulation layer 431 including dielectric material is formed on the transparent substrate 405 having the data electrode 421, the second storage capacitor electrode 422, the gate pad buffer layer 423 and the data pad 424 formed thereon, and a second insulation layer 432 including dielectric material is formed on the first insulation layer 431. An optically transparent and electrically conductive layer (not shown) is formed on the second insulation layer 432. The optically transparent and electrically conductive layer is patterned to form a pixel electrode 441. The pixel electrode 441 is electrically connected to the data line 304 (see FIG. 3) through a second contact hole 433 formed at the first and second insulation layers 431 and 432. The pixel electrode 441 may be constructed using for example, indium tin oxide (ITO), or indium zinc oxide (IZO). Indium tin oxide (ITO) and indium zinc oxide (IZO) are optically transparent and electrically conductive.

An image is displayed through a combination of pixels each of which has the above explained structure.

According to the present invention, an insulation layer associated with a TFT has different thickness from the insulation layer associated with the storage capacitor. More particularly, the first and second insulation layers are disposed between the gate electrode and the data electrode of the TFT, and only the first insulation layer is disposed between the first storage capacitor electrode and the second storage capacitor electrode. Therefore, a capacitance of the storage capacitor is enhanced without increasing the parasitic capacitance of the TFT, and therefor the aperture ratio is enhanced which produces an improved display quality.

Further, the first insulation layer including silicon oxide (SiOx) is disposed between the first and second storage capacitor electrodes, and the first and second gate insulation layers including silicon oxide (SiOx) and silicon nitride (SiNx), respectively, are disposed between the gate electrode and the data electrode of the TFT to enhance properties of the TFT.

Having described the exemplary embodiments of the present invention and its advantages, it is noted that various changes, substitutions and alterations can be made herein without departing from the spirit and scope of the invention as defined by appended claims.

What is claimed is:

1. An array substrate comprising:
a transparent substrate;
a thin film transistor including a gate electrode formed on the transparent substrate, a first gate insulating layer formed on the gate electrode, a second gate insulating layer formed on the first gate insulating layer, a semiconductor layer formed on the second gate insulating layer, and a data electrode formed on the semiconductor layer;
a pixel electrode electrically connected to the data electrode; and
a storage capacitor comprising a first electrode positioned in spaced apart relationship from the gate electrode, and a second electrode formed on the first gate insulating layer such that the second electrode is disposed over the first electrode, wherein the second electrode is constructed from a material which is used to form the data electrode.

2. The array substrate of claim 1, further comprising:
a gate pad electrode spaced apart from the gate electrode, and wherein the first electrode, the gate pad electrode, the gate electrode and the first electrode are formed from a common metal layer; and
a gate pad buffer layer that is electrically connected to the gate pad electrode through a first contact hole formed at the first gate insulation layer.

3. The array substrate of claim 1, wherein an etching selection ratio of the first gate insulating layer to the second gate insulating layer is higher than 10:1.

4. The array substrate of claim 3, wherein the first gate insulating layer includes silicon oxide.

5. The array substrate of claim 3, wherein the second gate insulating layer includes silicon nitride.

6. The array substrate of claim 1, wherein the pixel electrode includes one of indium tin oxide (ITO) and indium zinc oxide (IZO).

7. The array substrate of claim 1, wherein the data electrode is comprised of at least one material selected from the group consisting of chromium (Cr), aluminum (Al), molybdenum (Mo), tungsten (W), copper (Cu), neodymium (Nd), and an alloy of any one of Cr, Al, Mo, W, Ca and Nd.

8. A method of manufacturing an array substrate, comprising:
forming a gate electrode, a first capacitor electrode and a gate line that is electrically connected to the gate electrode by patterning a metal layer on a transparent substrate;
forming a first gate insulating layer on the transparent substrate having the gate electrode, the first capacitor electrode and the gate line formed thereon;
forming a second gate insulating layer and a semiconductor layer in a thin film transistor region corresponding to the gate electrode by removing a portion of a preliminary second insulation layer and a preliminary semiconductor layer formed on the preliminary second insulation layer;
forming a data electrode, a second storage capacitor electrode corresponding to the first storage capacitor electrode, and a data line that is electrically connected to the data electrode by patterning a metal layer formed on the transparent substrate having the semiconductor layer formed thereon;
forming a second contact hole by removing a portion of an insulation layer formed on the transparent substrate having the data electrode, the second storage capacitor electrode and the data line formed thereon; and
forming a pixel electrode that is electrically connected to the data electrode through the second contact hole by patterning an optically transparent and electrically conductive layer formed on the insulation layer having the second contact hole.

9. A method of manufacturing an array substrate, comprising:
forming a gate electrode, a first capacitor electrode, a gate line that is electrically connected to the gate electrode, and a gate pad by patterning a metal layer formed on a transparent substrate;
forming a first gate insulation layer on the transparent substrate having the gate electrode, the first capacitor electrode and the gate line formed thereon;
forming a second gate insulation layer and a semiconductor layer in a thin film transistor region corresponding to the gate electrode by removing a portion of a preliminary second insulation layer and a preliminary semiconductor layer formed on the preliminary second insulation layer;
removing a portion of the first insulation layer to form a first contact hole that exposes the gate pad;
forming a data electrode, a second storage capacitor electrode corresponding to the first storage capacitor electrode, a gate pad buffer layer that is electrically connected to the gate pad through the first contact hole, and a data line that is electrically connected to the data electrode by patterning a metal layer formed on the transparent substrate having the semiconductor layer formed thereon;
forming a second contact hole by removing a portion of an insulation layer formed on the transparent substrate having the data electrode, the second storage capacitor electrode and the data line formed thereon; and
forming a pixel electrode that is electrically connected to the data electrode through the second contact hole by patterning an optically transparent and electrically conductive layer formed on the insulation layer having the second contact hole.

10. A display apparatus comprising:
a liquid crystal capacitor that is electrically connected to a thin film transistor having a gate electrode, a data electrode including a source electrode and a drain electrode that is spaced apart from the source electrode, and a gate insulating layer disposed between the gate electrode and the data electrode; and
a storage capacitor electrically connected in parallel with the liquid crystal capacitor, wherein the storage capacitor includes a first electrode, a second electrode and an insulating layer disposed between the first and second electrodes,
and further wherein a thickness of the gate insulating layer associated with the thin film transistor is greater than a thickness of the insulating layer associated with the storage capacitor.

11. The display apparatus of claim 10, wherein the gate insulating layer associated with the thin film transistor includes a first layer and a second layer, and the gate insulating layer associated with the storage capacitor includes only the first layer.

12. The display apparatus of claim 10, wherein the gate insulating layer is comprised of a first layer of material and a second layer of material, and further wherein an etching selection ratio of the first layer to the second layer is higher than 10:1.

13. The display apparatus of claim 11, wherein the first layer is comprised of an oxide of silicon, and the second layer includes silicon nitride.
